(19) United States
(12) Patent Application Publication
(10) Pub. No.: US 2013/0193483 A1
(43) Pub. Date: Aug. 1, 2013

(54) Mosfet Structures Having Compressively Strained Silicon Channel

(71) Applicants: Stephen W. Bedell, Wappingers Falle, NY (US); Kangguo Cheng, Schenectady, NY (US); Bahman Hekmatshoartabari, White Plains, NY (US); Ali Khakifirooz, Mountain View, CA (US); Alexander Reznicek, Mount Kisco, NY (US); Devendra K. Sadana, Pleasantville, NY (US); Ghavam G. Shahidi, Pound Ridge, NY (US); Davood Shahrjerdi, Ossining, NY (US)

(72) Inventors: Stephen W. Bedell, Wappingers Falle, NY (US); Kangguo Cheng, Schenectady, NY (US); Bahman Hekmatshoartabari, White Plains, NY (US); Ali Khakifirooz, Mountain View, CA (US); Alexander Reznicek, Mount Kisco, NY (US); Devendra K. Sadana, Pleasantville, NY (US); Ghavam G. Shahidi, Pound Ridge, NY (US); Davood Shahrjerdi, Ossining, NY (US)

(73) Assignee: INTERNATIONAL BUSINESS MACHINES CORPORATION, Armonk, NY (US)

(21) Appl. No.: 13/359,858

(22) Filed: Jan. 27, 2012

(51) Int. Cl. H01L 27/088; H01L 21/336

(52) U.S. Cl. 257/192; 438/151; 438/285; 257/347; 257/E27.06; 257/E21.409

(57) ABSTRACT

MOSFET structures are provided having a compressively strained silicon channel. A semiconductor device is provided that comprises a field effect transistor (FET) structure having a gate stack on a silicon substrate, wherein the field effect transistor structure comprises a channel formed below the gate stack; and a compressively strained silicon layer on at least a portion of the silicon substrate to compressively strain the channel.

### FIELD OF THE INVENTION

The present invention relates generally to semiconductor devices, and, more particularly, to such semiconductor devices having compressively strained Silicon channels.

### BACKGROUND OF THE INVENTION

Conventional Metal Oxide Semiconductor (MOS) technology integration schemes are increasingly pushed to reduce device dimensions. The downscaling of the physical dimensions of Metal Oxide Semiconductor Field Effect Transistors (MOSFETs) has led to performance improvements of integrated circuits and an increase in the number of transistors per chip. For example, current integration schemes are attempting to reduce technology node dimensions to 22 nanometers (nm) or less. As the device dimensions are reduced to these small values, a number of problems have been identified related to geometry effects. For example, the addition of some technology boosters, such as an application of strain to the channel and high dielectric constant (“high k”) gate material appears to be crucial for maintaining the scaling trend of MOSFETs. Various strain engineering techniques are employed to modulate strain in the transistor channel, in order to enhance the carrier (electron or hole) transport. Strained silicon is generally understood as a layer of silicon wherein the silicon atoms have been stretched out or contracted beyond their normal interatomic distance.

Some examples of these techniques include embedded silicon germanium (e-SiGe) in source/drain regions, stress liners, epitaxial growth of strained Silicon (Si) channel on relaxed SiGe, and epitaxial growth of strained SiGe channel on Silicon. The aggressive scaling of the MOSFET pitch, however, has increasingly diminished the effectiveness of some process-induced strain technologies, such as the stress liners and the embedded SiGe. A need therefore exists for improved strain engineering techniques.

Epitaxial growth of strained channels has been suggested as a viable option for inducing additional strain. It is known that electron and hole transport properties can be enhanced by tensile and compressive strains, respectively. The latter is conventionally achieved by the growth of SiGe directly on Si, wherein the amount of strain increases with the Ge content. The increase of the transistor off current due to the reduction of the SiGe bandgap as a result of the increase in the Ge content can, however, counteract the performance enhancement achieved by the higher strain level in SiGe.

U.S. patent application Ser. No. 13/037,944, filed Mar. 1, 2011, entitled “Growing Compressively Strained Silicon Directly on Silicon at Low Temperatures,” incorporated by reference herein, discloses techniques for growing compressively strained Silicon on Silicon at low temperatures. A need remains for MOSFET structures having compressively strained Silicon channels.

### SUMMARY OF THE INVENTION

Generally, MOSFET structures are provided having a compressively strained silicon channel. According to one aspect of the invention, a semiconductor device is provided that comprises a field effect transistor (FET) structure having a gate stack on a silicon substrate, wherein the field effect transistor structure comprises a channel formed below the gate stack; and a compressively strained silicon layer on at least a portion of the silicon substrate to compressively strain the channel.

The compressively strained silicon layer can be formed, for example, on the portion of the silicon substrate at low temperatures. The compressively strained silicon layer can comprise, for example, (i) a highly doped epitaxial embedded silicon layer formed on the portion of the silicon substrate in one or more recessed source/drain pockets below spacers; (ii) an undoped epitaxial embedded silicon layer formed on the portion of the silicon substrate in the channel and further comprising a layer of embedded silicon germanium in one or more recessed source/drain pockets below spacers; or (iii) an undoped epitaxial embedded silicon layer fowled on the portion of the silicon substrate in the channel and a compressively strained, highly doped epitaxial embedded silicon layer formed in one or more recessed source/drain pockets below spacers.

A more complete understanding of the present invention, as well as further features and advantages of the present invention, will be obtained by reference to the following detailed description and drawings.

### BRIEF DESCRIPTION OF THE DRAWINGS

FIG. 1 is a sectional view of an exemplary wafer manufactured pursuant to the techniques described in. U.S. patent application Ser. No. 13/037,944;

FIGS. 2 and 3 illustrate cross-sectional views of an exemplary p-channel MOSFET (pFET) structure after being processed in a known manner to provide recessed source/drain pockets below spacers adjacent to a gate stack;

FIG. 4 illustrates an exemplary wafer comprising a compressively strained, highly doped epitaxial embedded silicon layer grown on a crystalline silicon substrate;

FIGS. 5 and 6 illustrate cross-sectional views of exemplary pFET structures incorporating aspects of the present invention;

FIG. 7 illustrates an exemplary wafer comprising a compressively strained, undoped epitaxial embedded silicon layer grown on a crystalline silicon substrate; and

FIGS. 8 through 11 illustrate cross-sectional views of exemplary pFET structures according to alternate embodiments of the present invention.

### DETAILED DESCRIPTION OF PREFERRED EMBODIMENTS

The present invention provides a number of improved MOSFET structures having compressively strained Silicon channels. FIG. 1 is a sectional view of an exemplary wafer 10 manufactured pursuant to the techniques described in U.S. patent application Ser. No. 13/037,944, filed Mar. 1, 2011, entitled “Growing Compressively Strained Silicon Directly on Silicon at Low Temperatures,” incorporated by reference herein. The wafer 10 includes a crystalline silicon substrate 12 and a compressively strained, epitaxial silicon layer 14 deposited directly thereon. The layer 14 can optionally include elements in addition to silicon, but does not necessarily require such elements other than hydrogen in an amount sufficient to impart the desired strain. In addition, the substrate 12 does not need to be comprised entirely of crystalline silicon. It is only necessary that the surface upon which the silicon layer is formed be comprised of crystalline silicon. In the exemplary embodiment of FIG. 1. the strain in the layer 14 is substantially uniform throughout and at least partially attributable to hydrogen atoms incorporated in the layer.

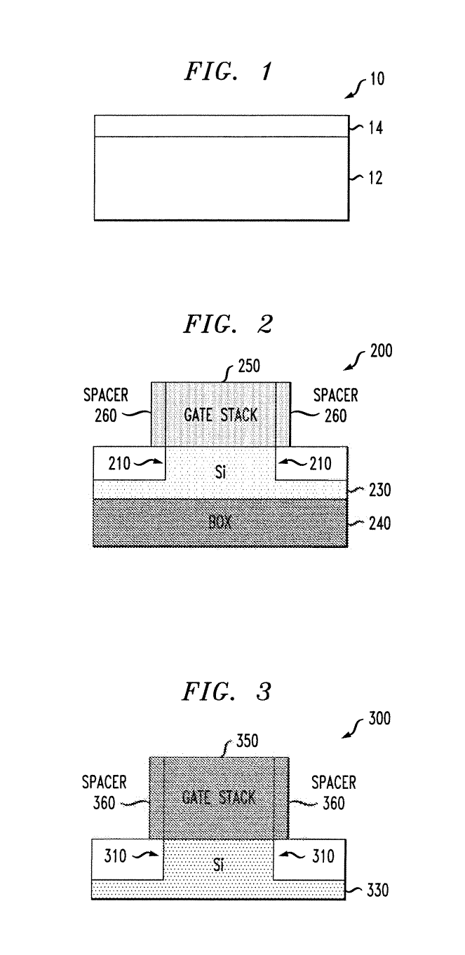

FIG. 2 illustrates a cross-sectional view of an exemplary p-channel MOSFET (pFET) structure 200 after being processed in a known manner to provide recessed source/drain pockets 210 below spacers 260. As shown in FIG. 2, the exemplary pFET structure 200 is formed on a Silicon-On-Insulator (SOI) wafer comprising one or more silicon substrate layers 230 and a buried oxide (BOX) layer 240. A gate stack 250 is formed above the top silicon layer 230. The gate stack 250 can be comprised of, for example, a gate dielectric layer and a gate conductor layer (not shown). As is known in the art, the exact composition of the gate stack 250 may be altered to optimize transistor performance. The spacers 260 are provided on the sidewalls of the gate stacks 250. The spacers 260 are typically comprised of an oxide, nitride or oxynitride material, including combinations and multilayers thereof. The spacers 260 may serve to protect the sidewalls of the gate stack 250 during subsequent processing, in a known manner.

As discussed hereinafter, a compressively strained Silicon layer is formed on the top Silicon substrate layer 230 in the recessed source/drain pockets 210 below spacers 260, in accordance with aspects of the present invention.

The recessed source/drain pockets 210 below spacers 260 may be obtained by exposing the top silicon substrate layer 230 to a reactive ion etching (RIE) or another suitable process to form the recesses 210 in the region below the spacers 260. A reactive ion etching (RIE) process or another suitable process will remove portions of the top silicon layer 230. The etchant selectively removes the silicon layer 230 under the spacer regions 260 and may be, for example, HCl, Chlorine, Fluorine, SF6 and other etchant gases and mixtures of thereof.

FIG. 3 illustrates a cross-sectional view of an alternate exemplary p-channel MOSFET (pFET) structure 300 after being processed in a known manner to provide recessed source/drain pockets 310 below spacers 360. As shown in FIG. 3, the exemplary pFET structure 300 is formed on a bulk substrate comprising at least one more silicon substrate layer 330. A gate stack 350 is formed above the top silicon layer 330. The gate stack 350 can be comprised of, for example, a gate dielectric layer and a gate conductor layer (not shown). As is known in the art, the exact composition of the gate stack 350 may be altered to optimize transistor performance. The spacers 360 are provided on the sidewalls of the gate stacks 350. The spacers 360 are typically comprised of an oxide, nitride or oxynitride material, including combinations and multilayers thereof. The spacers 360 may serve to protect the sidewalls of the gate stack 350 during subsequent processing, in a known manner.

As indicated above, a compressively strained Silicon layer formed on a Silicon substrate is formed in the recessed source/drain pockets 310 below spacers 360 in accordance with aspects of the present invention.

The recessed source/drain pockets 310 below spacers 360 may be obtained in a similar manner to FIG. 2.

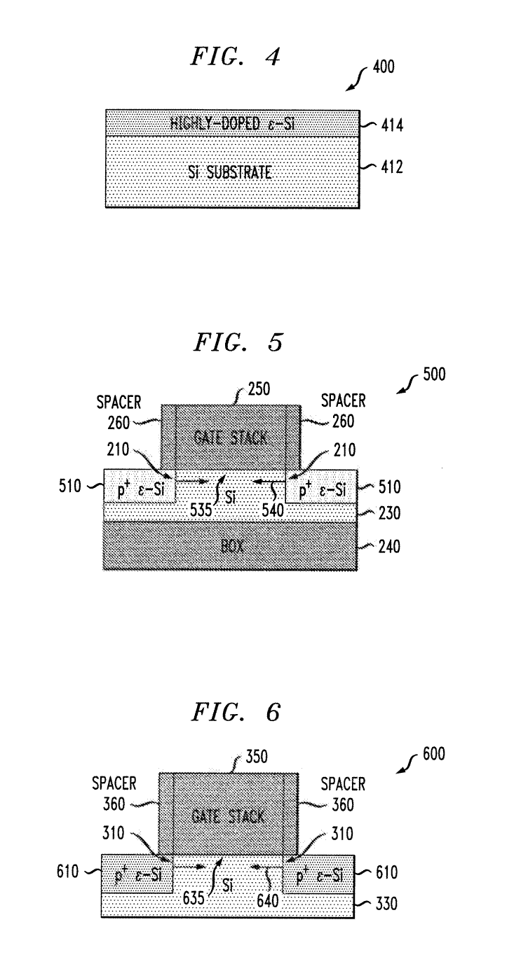

FIG. 4 illustrates an exemplary wafer 400 manufactured pursuant to the techniques described in U.S. patent application Ser. No. 13/037,944, filed Mar. 1, 2011, entitled “Growing Compressively Strained Silicon Directly on Silicon at Low Temperatures,” incorporated by reference herein. The exemplary structure 400 of FIG. 4 is employed by the embodiments of FIGS. 5 and 6 to fill the recessed source/drain pockets 210, 310 in order to exert a uniaxial compressive strain to the channel.

As shown in FIG. 4, the wafer 400 comprises a crystalline silicon substrate 412 and a compressively strained, highly doped epitaxial embedded silicon layer 414 grown directly thereon. The dopant materials may comprise, for example, an acceptor dopant, such as Boron, that can be incorporated in-situ with the epitaxial growth process. It can be shown that the wafer 400 of FIG. 4 exhibits a compressive strain of approximately 0.23%.

FIG. 5 illustrates a cross-sectional view of an exemplary pFET structure 500 incorporating aspects of the present invention. As shown in FIG. 5, the exemplary pFET structure 500 employs the structure 400 of FIG. 4 to fill the recessed source/drain pockets 210, in order to exert a uniaxial compressive strain 540 to the channel 535. The exemplary pFET structure 500 is formed on a Silicon-On-Insulator (SOI) wafer comprising one or more silicon substrate layers 230 and a buried oxide (BOX) layer 240, in a similar manner to FIG. 2. A gate stack 250 is formed above the top silicon layer 230. The gate stack 250 can he comprised of, for example, a gate dielectric layer and a gate conductor layer (not shown). As is known in the art, the exact composition of the gate stack 250 may be altered to optimize transistor performance. The spacers 260 are provided on the sidewalls of the gate stacks 250. The spacers 260 are typically comprised of an oxide, nitride or oxynitride material, including combinations and multilayers thereof. The spacers 260 may serve to protect the sidewalls of the gate stack 250 during subsequent processing, in a known manner.

As shown in FIG. 5, a compressively strained, highly doped epitaxial embedded silicon layer 510 is formed on the top Silicon substrate layer 230 in the recessed source/drain pockets 210 below spacers 260, using the techniques of FIG. 4 and in accordance with aspects of the present invention. The recessed source/drain pockets 210 below spacers 260 may be obtained in a similar manner to FIG. 2.

FIG. 6 illustrates a cross-sectional view of an alternate exemplary pFET structure 600 incorporating aspects of the present invention. As shown in FIG. 6, the exemplary pFET structure 600 employs the structure 400 of FIG. 4 to fill the recessed source/drain pockets 310, in order to exert a uniaxial compressive strain 640 to the channel 635. As shown in FIG. 6, the exemplary pFET structure 600 is formed on a bulk substrate comprising at least one more silicon substrate layer 330. A gate stack 350 is formed above the top silicon layer 330. The gate stack 350 can be comprised of, for example, a gate dielectric layer and a gate conductor layer (not shown). As is known in the art, the exact composition of the gate stack 350 may be altered to optimize transistor performance. The spacers 360 are provided on the sidewalls of the gate stacks 350. The spacers 360 are typically comprised of an oxide, nitride or oxynitride material, including combinations and multilayers thereof. The spacers 360 may serve to protect the sidewalls of the gate stack 350 during subsequent processing, in a known manner.

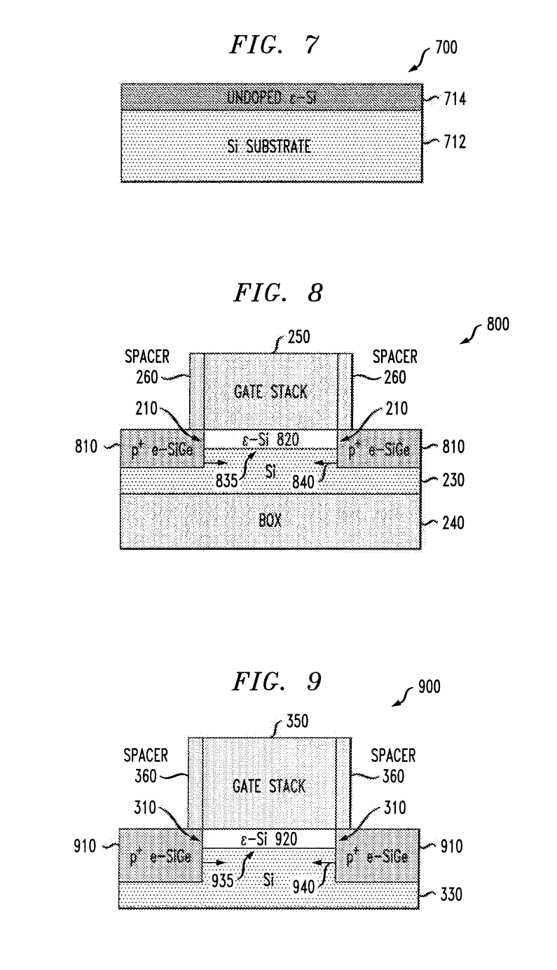

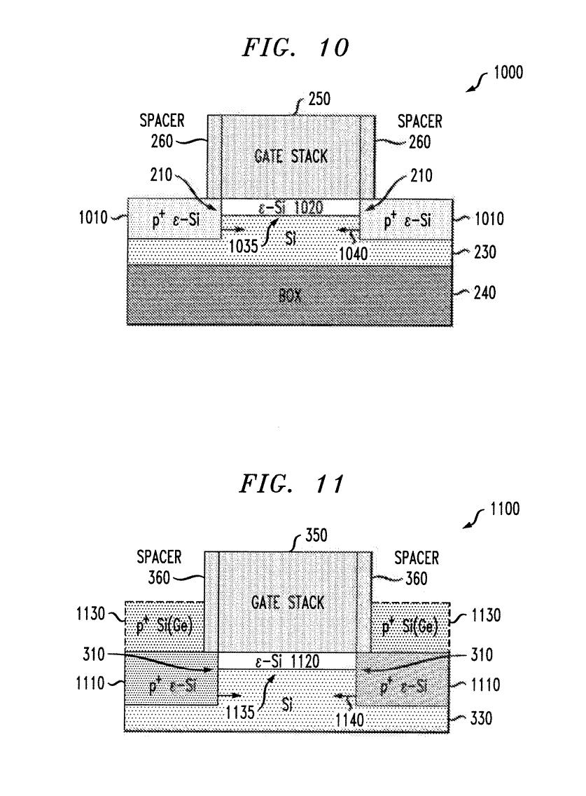

As shown in FIG. 6, a compressively strained, highly doped epitaxial embedded silicon layer 610 is formed on the top Silicon substrate layer 330 in the recessed source/drain pockets 310 below spacers 360, using the techniques of FIG. 4 and in accordance with aspects of the present invention. The recessed source/drain pockets 310 below spacers 360 may be obtained in a similar manner to FIG. 2. FIG. 7 illustrates an exemplary wafer 700 manufactured pursuant to the techniques described in U.S. patent application Ser. No. 13/037,944, filed Mar. 1, 2011, entitled “Growing Compressively Strained Silicon Directly on Silicon at Low Temperatures,” incorporated by reference herein. The exemplary structure 700 of FIG. 7 is employed by the embodiments of FIGS. 8 and 9 to fill the channel region in order to exert a compressive strain to the channel. The strain can be either uniaxial or biaxial depending on the dimensions and the geometry of the channel. Long and narrow channel geometry is preferred to exert a uniaxial strain.

As shown in FIG. 7, the wafer 700 comprises a crystalline silicon substrate 712 and a compressively strained, undoped epitaxial embedded silicon layer 714 grown directly thereon. It can be shown that the wafer 700 of FIG. 7 exhibits a compressive strain of approximately 0.8%.

FIG. 8 illustrates a cross-sectional view of an exemplary pFET structure 800 incorporating aspects of the present invention. As shown in FIG. 8, the exemplary pFET structure 800 employs the structure 700 of FIG. 7 to fill the channel region 835 and thereby exert a uniaxial compressive strain 840 to the channel 835. In addition, a layer 810 of embedded silicon germanium (e-SiGe) is formed in the recessed source/drain pockets 210 of FIG. 2.

The exemplary pFET structure 800 is formed on a Silicon-On-Insulator (SOI) wafer comprising one or more silicon substrate layers 230 and a buried oxide (BOX) layer 240, in a similar manner to FIG. 2. A gate stack 250 is formed above the top silicon layer 230. The gate stack 250 can be comprised of, for example, a gate dielectric layer and a gate conductor layer (not shown). As is known in the art, the exact composition of the gate stack 250 may be altered to optimize transistor performance. The spacers 260 are provided on the sidewalls of the gate stacks 250. The spacers 260 are typically comprised of an oxide, nitride or oxynitride material, including combinations and multilayers thereof. The spacers 260 may serve to protect the sidewalls of the gate stack 250 during subsequent processing, in a known manner.

As shown in FIG. 8, a compressively strained, undoped epitaxial embedded silicon layer 820 is formed on the top Silicon substrate layer 230 in the channel region 835, using the techniques of FIG. 7, and a layer 810 of e-SiGe is formed in the recessed source/drain pockets 210 below spacers 260, in accordance with aspects of the present invention. The recessed source/drain pockets 210 below spacers 260 may be obtained in a similar manner to FIG. 2.

FIG. 9 illustrates a cross-sectional view of an alternate exemplary pFET structure 900 incorporating aspects of the present invention. As shown in FIG. 9, the exemplary pFET structure 900 employs the structure 700 of FIG. 7 to fill the channel region 935 and thereby exert a uniaxial compressive strain 940 to the channel 935. In addition, a layer 910 of embedded silicon germanium (e-SiGe) is formed in the recessed source/drain pockets 310 of FIG. 3.

As shown in FIG. 9, the exemplary pFET structure 900 is formed on a bulk substrate comprising at least one more silicon substrate layer 330. A gate stack 350 is formed above the top silicon layer 330. The gate stack 350 can be comprised of, for example, a gate dielectric layer and a gate conductor layer (not shown). As is known in the art, the exact composition of the gate stack 350 may be altered to optimize transistor performance. The spacers 360 are provided on the sidewalls of the gate stacks 350. The spacers 360 are typically comprised of an oxide, nitride or oxynitride material, including combinations and multilayers thereof. The spacers 360 may serve to protect the sidewalls of the gate stack 350 during subsequent processing, in a known manner.

As shown in FIG. 9, compressively strained, undoped epitaxial embedded silicon layer 920 is formed on the top Silicon substrate layer 330 in the channel region 935, using the techniques of FIG. 7, and a layer 910 of e-SiGe is formed in the recessed source/drain pockets 310 below spacers 360, in accordance with aspects of the present invention. The recessed source/drain pockets 310 below spacers 360 may be obtained in a similar manner to FIG. 2.

FIG. 10 illustrates a cross-sectional view of an exemplary pFET structure 1000 incorporating aspects of the present invention. As shown in FIG. 10, the exemplary pFET structure 1000 employs aspects of the structures 400 and 800 of FIGS. 4 and 8, respectively. As shown in FIG. 10, the exemplary pFET structure 1000 employs a compressively strained, undoped epitaxial embedded silicon layer 1020 in the channel region 1035, using the techniques of FIG. 7, to exert a uniaxial compressive strain 1040 to the channel 1035. In addition, a compressively strained, highly doped epitaxial embedded silicon layer 1010 is formed in the recessed source/drain pockets 210.

The exemplary pFET structure 1000 is formed on a Silicon-On-Insulator (SOI) wafer comprising one or more silicon substrate layers 230 and a buried oxide (BOX) layer 240, in a similar manner to FIG. 2. A gate stack 250 is formed above the top silicon layer 230. The gate stack 250 can be comprised of, for example, a gate dielectric layer and a gate conductor layer (not shown). As is known in the art, the exact composition of the gate stack 250 may be altered to optimize transistor performance. The spacers 260 are provided on the sidewalls of the gate stacks 250. The spacers 260 are typically comprised of an oxide, nitride or oxynitride material, including combinations and multilayers thereof. The spacers 260 may serve to protect the sidewalls of the gate stack 250 during subsequent processing, in a known manner.

As shown in FIG. 10, a compressively strained, undoped epitaxial embedded silicon layer 1020 is formed on the top Silicon substrate layer 230 in the channel region 1035, using the techniques of FIG. 7, and a layer 1010 of a compressively strained, highly doped epitaxial embedded silicon is formed in the recessed source/drain pockets 210 below spacers 260, in accordance with aspects of the present invention. The recessed source/drain pockets 210 below spacers 260 may be obtained in a similar manner to FIG. 2.

FIG. 11 illustrates a cross-sectional view of an alternate exemplary pFET structure 1100 incorporating aspects of the present invention. As shown in FIG. 11, the exemplary pFET structure 1100 employs a compressively strained, undoped epitaxial embedded silicon layer 1120 in the channel region 1135, using the techniques of FIG. 7, to exert a uniaxial compressive strain 1140 to the channel 1135. In addition, a compressively strained, highly doped epitaxial embedded silicon layer 1110 is formed in the recessed source/drain pockets 310.

As shown in FIG. 11, the exemplary pFET structure 1100 is formed on a bulk substrate comprising at least one more silicon substrate layer 330. A gate stack 350 is formed above the top silicon layer 330. The gate stack 350 can be comprised of, for example, a gate dielectric layer and a gate conductor layer (not shown). As is known in the art, the exact composition of the gate stack 350 may be altered to optimize transistor performance. The spacers 360 are provided on the sidewalls of the gate stacks 350. The spacers 360 are typically comprised of an oxide, nitride or oxynitride material, including combinations and multilayers thereof. The spacers 360 may serve to protect the sidewalls of the gate stack 350 during subsequent processing, in a known manner.

As shown in FIG. 11, a compressively strained, undoped epitaxial embedded silicon layer 1120 is formed on the top Silicon substrate layer 330 in the channel region 1135, using the techniques of FIG. 7, and a layer 1110 of compressively strained, highly doped epitaxial embedded silicon is formed in the recessed source/drain pockets 310 below spacers 360, in accordance with aspects of the present invention. The recessed source/drain pockets 310 below spacers 360 may be obtained in a similar manner to FIG. 2. As shown in FIG. 11, the alternate exemplary pl-ET structure 1100 optionally further comprises raised source/drain regions 1130 grown on the embedded S/D regions. The optional raised source/drain regions 1130 further reduce the series resistance, in a known manner. The raised source/drain regions 1130 can be comprised of, for example, SiₓGe₁₋ₓ with 0.5<x<1. The raised source/drain regions 1130 shown in FIG. 11 can optionally be added to all of the pFET structures described herein, as would be apparent to a person of ordinary skill in the art.

The disclosed techniques can be employed in combination with other methods to further enhance the strain in the channel, such as stress liners and strained channels. The foregoing description discloses only exemplary embodiments of the invention. Modifications of the above disclosed structures and method which fall within the scope of the invention will be readily apparent to those of ordinary skill in the art. Accordingly, while the present invention has been disclosed in connection with exemplary embodiments thereof, it should be understood that other embodiments may fall within the spirit and scope of the invention, as defined by the following claims.

The terminology used herein is for the purpose of describing particular embodiments only and is not intended to be limiting of the invention. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

The corresponding structures, materials, acts, and equivalents of all means or step plus function elements in the claims below are intended to include any structure, material, or act for performing the function in combination with other claimed elements as specifically claimed. The description of the present invention has been presented for purposes of illustration and description, but is not intended to be exhaustive or limited to the invention in the form disclosed. Many modifications and variations will be apparent to those of ordinary skill in the art without departing from the scope and spirit of the invention. The embodiments were chosen and described in order to best explain the principles of the invention and the practical application, and to enable others of ordinary skill in the art to understand the invention for various embodiments with various modifications as are suited to the particular use contemplated.

What is claimed is:

1. A semiconductor device, comprising:
a field effect transistor (FET) structure having a gate stack on a silicon substrate, wherein said field effect transistor structure comprises a channel formed below said gate stack; and
a compressively strained silicon layer on at least a portion of said silicon substrate to compressively strain said channel.

2. The semiconductor device of claim 1, wherein said compressively strained silicon layer is formed on said at least a portion of said silicon substrate at low temperatures.

3. The semiconductor device of claim 1, wherein said silicon substrate comprises one or more of a bulk wafer and a Silicon-On-Insulator (SOI) wafer.

4. The semiconductor device of claim 1, wherein said compressively strained silicon layer comprises a highly doped epitaxial embedded silicon layer formed on said at least a portion of said silicon substrate in one or more recessed source/drain pockets below spacers.

5. The semiconductor device of claim 1, wherein said compressively strained silicon layer comprises an undoped epitaxial embedded silicon layer formed on said at least a portion of said silicon substrate in said channel and further comprising a layer of embedded silicon germanium in one or more recessed source/drain pockets below spacers.

6. The semiconductor device of claim 1, wherein said compressively strained silicon layer comprises an undoped epitaxial embedded silicon layer formed on said at least a portion of said silicon substrate in said channel and a compressively strained, highly doped epitaxial embedded silicon layer formed in one or more recessed source/drain pockets below spacers.

7. The semiconductor device of claim 1, wherein said semiconductor device is embodied on a CMOS circuit and wherein the FET structure comprises a pFET structure.

8. The semiconductor device of claim 1, further comprising one or more raised source/drain regions.

9. A method of forming a semiconductor device, comprising:
obtaining a field effect transistor (FET) structure having a gate stack on a silicon substrate, wherein said field effect transistor structure comprises a channel formed below said gate stack; and
forming a compressively strained silicon layer on at least a portion of said silicon substrate to compressively strain said channel.

10. The method of claim 9, wherein said compressively strained silicon layer is formed on said at least a portion of said silicon substrate at low temperatures.

11. The method of claim 9, wherein said silicon substrate comprises one or more of a bulk wafer and a Silicon-On-Insulator (SOI) wafer.

12. The method of claim 9, wherein said compressively strained silicon layer comprises a highly doped epitaxial embedded silicon layer formed on said at least a portion of said silicon substrate in one or more recessed source/drain pockets below spacers.

13. The method of claim 9, wherein said compressively strained silicon layer comprises an undoped epitaxial embedded silicon layer formed on said at least a portion of said silicon substrate in said channel and further comprising the step of forming a layer of embedded silicon germanium in one or more recessed source/drain pockets below spacers.

14. The method of claim 9, wherein said compressively strained silicon layer comprises an undoped epitaxial embedded silicon layer formed on said at least a portion of said silicon substrate in said channel and a compressively strained, highly doped epitaxial embedded silicon layer formed in one or more recessed source/drain pockets below spacers.

15. The method of claim 9, further comprising the step of forming one or more raised source/drain regions.

16. A CMOS circuit, comprising:
a p-channel field effect transistor (FET) structure having a gate stack on a silicon substrate, wherein said field effect transistor structure comprises at least a channel formed below said gate stack; and
a compressively strained silicon layer on at least a portion of said silicon substrate to compressively strain said channel.

17. The CMOS circuit of claim 16, wherein said compressively strained silicon layer is formed on said at least a portion of said silicon substrate at low temperatures.

18. The CMOS circuit of claim 16, wherein said silicon substrate comprises one or more of a bulk wafer and a Silicon-On-Insulator (SOD wafer.

19. The CMOS circuit of claim 16, wherein said compressively strained silicon layer comprises a highly doped epitaxial embedded silicon layer formed on said at least a portion of said silicon substrate in one or more recessed source/drain pockets below spacers.

20. The CMOS circuit of claim 16, wherein said compressively strained silicon layer comprises an undoped epitaxial embedded silicon layer formed on said at least a portion of said silicon substrate in said channel and further comprising a layer of embedded silicon germanium in one or more recessed source/drain pockets below spacers.

21. The CMOS circuit of claim 16, wherein said compressively strained silicon layer comprises an undoped epitaxial embedded silicon layer formed on said at least a portion of said silicon substrate in said channel and a compressively strained, highly doped epitaxial embedded silicon layer formed in one or more recessed source/drain pockets below spacers.

22. The CMOS circuit of claim 16, further comprising one or more raised source/drain regions.
